(19) United States
(12) Patent Application Publication
(10) Pub. No.: US 2017/0370974 A1
(43) Pub. Date: Dec. 28, 2017

(54) METHOD AND SYSTEM FOR PROVIDING SOUND DATA FOR GENERATION OF AUDIBLE NOTIFICATION RELATING TO POWER CONSUMPTION

(71) Applicant: TELEFONAKTIEBOLAGET LM ERICSSON (PUBL), Stockholm (SE)

(72) Inventors: Hongxin LIANG, Upplands Väsby (SE); Athanasios KARAPANTELAKIS, Stockholm (SE); Patrik OLDSBERG, Tyresö (SE); Vlasios TSIATSIS, Solna (SE)

(73) Assignee: TELEFONAKTIEBOLAGET LM ERICSSON (PUBL), Stockholm (SE)

(21) Appl. No.: 15/516,068

(22) PCT Filed: Oct. 7, 2014
(86) PCT No.: PCT/SE2014/051174

§ 371 Date: Mar. 31, 2017

(51) Int. Cl. G01R 22/06; G01D 7/12; G05B 15/02; G01D 4/16; G01R 11/00

(52) U.S. Cl. CPC G01R 22/063; G05B 15/02; G01D 4/16; G01D 7/12; G01R 11/00

(57) ABSTRACT

A method and a system (110) for providing sound data for generation of an audible notification relating to power consumption at a site (120) are disclosed. The system receives (201) information about power consumption at the site (120); and The system determines (202) the sound data based on the information about power consumption and on preference of a user of the system (110). A corresponding computer program and a carrier therefor are also disclosed.

### TECHNICAL FIELD

The present disclosure relates to the field of monitoring systems for monitoring power consumption. In particular, a method and a system for providing sound data for generation of an audible notification relating to power consumption at a site are disclosed. A corresponding computer program and a carrier therefor are also disclosed.

### BACKGROUND

Within the field of monitoring systems for monitoring power consumption, an International Energy Agency (IEA) regularly provides statistics about trends and amounts of power consumption, such as electrical power consumption. Statistics, from the IEA available in the fall of 2014, reveals that there has been an increase in average power consumption per capita of 18.75% in the last decade. At the same time, price of electricity in developed parts of the world has increased. In the United States (US), the price of electricity has increased by 50% from 2003 to 2014, and in Europe, the price of electricity has increased by 17% from 2009 to 2014.

Consumers, including households, industries, organizations and the like, begin to care more and more about power consumption, due to economic and/or environmental reasons.

There are quite many tools for power consumption data analysis and visualization, available on the market today. These tools include capabilities for visualization on both the web and/or on mobile devices.

Furthermore, it is known that when surveyed consumers receive feedback about their power consumption, it may have an effect of a 5-20% reduction of the power consumption. The exact reduction of the power consumption may depend on type of the feedback, population and survey characteristics. In many cases, a real-time feedback to the consumers in a detailed manner, such as power consumption on a per device basis, has greater gains than more general feedback.

A known tool for providing feedback about power consumption and visualization of the feedback may for example show a graph to indicate a current level of power consumption. Furthermore, the known tool may provide basic feedback in the form of a notification message that is displayed when a value is below or above a threshold.

Although, the tools that visualize power consumption have a perceived value of power consumption awareness for their users, the tools are not always convenient or even possible to use. A disadvantage is that the users need to pay attention, e.g. by looking at a screen of a visualization and feedback tool for power consumption awareness.

### SUMMARY

An object is to provide an improved system for providing feedback of power consumption, which system may be a tool of the above mentioned kind.

According to an aspect, the object is achieved by a method, performed by a system, for providing sound data for generation of an audible notification relating to power consumption at a site. The system receives information about power consumption at the site. The system determines the sound data based on the information about power consumption and on preference of a user of the system.

According to another aspect, the object is achieved by a system configured to provide sound data for generation of an audible notification relating to power consumption at a site. The system is configured to receive information about power consumption at the site. Moreover, the system is configured to determine the sound data based on the information about power consumption and on preference of a user of the system.

With the embodiments herein, there is provided a system which enables improved feedback capabilities for generation of the audible notification relating to power consumption, e.g. a measurement of current power consumption. The currently measured power consumption may be received in the form of the information about power consumption at the site. Thanks to that the sound data is based on the preference of the user, the user will more easily pay attention to the audible notification. In one exemplifying example, the user may be reluctant to pay attention to and note whether the power consumption increases or decreases if the user is required to observe a graph on a screen. Instead, according to some embodiments herein, the user may easily recognize that a volume of the user's choice of music increases or decreases as power consumption increases or decreases, respectively. Accordingly, the system facilitates how users may become aware of power consumption by enabling audible feedback according to the preference of the user, i.e. personalized and audible feedback is enabled.

An advantage is that the sound data enable provision of instant feedback of power consumption to the user, i.e. there may become a change in the audible notification upon when the user performs an action that affects the current power consumption.

Another advantage is that the system does not require visual attention of the user. Audio attention may, however, to some extent be preferred, but since the audible notification is based on the user's preference, such audio attention may be pleasant and non-intrusive to the user. The audio attention may be said to be non-intrusive, since the user may have selected an audible notification that is enjoyed and appreciated by the user.

Furthermore, the system may co-exist with existing power installations and devices.

### BRIEF DESCRIPTION OF THE DRAWINGS

The various aspects of embodiments disclosed herein, including particular features and advantages thereof, will be readily understood from the following detailed description and the accompanying drawings, in which:

FIG. 1 is a schematic overview of a structure in which embodiments herein may be implemented,

FIG. 2 is a diagram illustrating an exemplifying graph of power consumption versus time,

FIG. 3 is a flowchart illustrating embodiments of the method in the system,

FIG. 4 is a block diagram illustrating an exemplifying system, and

FIG. 5 is a block diagram illustrating embodiments of the system.

### DETAILED DESCRIPTION

Throughout the following description similar reference numerals have been used to denote similar features, such as actions, steps, nodes, elements, units, modules, circuits, parts, items or the like, when applicable. In the Figures, features that appear in some embodiments are indicated by dashed lines.

FIG. 1 depicts an exemplifying structure 100 in which embodiments herein may be implemented.

The structure 100 includes a system 110 for providing sound data for generation of the audible notification according to the embodiments herein and a site 120.

The sound data may be any representation of the audible notification that may be stored in a computer, such as the system 110. This means that the sound data may be a wav-, mpg3-, au-, flac-, ogg-, raw, acc-, aiff-, ra-, midi-, wma-file or the like.

The system 110 may communicate 132 with, such as send to, a speaker device 130, such as a load speaker, a headset or the like. In this example, the speaker device 130 may be connected to the system 110 via a wired or wireless audio connection, which connection is only capable of transferring audio related information, e.g. the audio data itself and possible some few control commands like ‘play’, ‘pause’, ‘skip’, etc. In other examples, the system 110 may include means (not shown) for generating the audible notification. The means may be any kind of means for generating sounds, such as speakers, headphones or the like.

The site 120, such as a house, an industry, a building, a train, an airplane or the like, may be defined by that a user or a group of users affects power consumption at the site 120 by which activities the user, or the group of users, performs. The site may include one or more appliances, such as dishwashers, vacuum cleaners, fridges, freezers, irons and the like.

The site 120 may be associated with one or more power meters, which may measure power consumption of appliances of the site. A power meter may measure the power consumption of one individual appliance or the power consumption of a group of appliances.

The system 110 may send and receive 121, e.g. via a wired or wireless connection, information to/from the site 120. The information may include measurements about current power consumption at the site.

The structure 100 may also comprise an electronic device 140, such as a user equipment, a machine-to-machine (M2M) device, a mobile phone, a cellular phone, a Personal Digital Assistant (PDA) equipped with radio communication capabilities, a smartphone, a laptop or Personal Computer (PC) equipped with an internal or external mobile broadband modem, a tablet PC with radio communication capabilities, a portable electronic radio communication device, a home automation system, a home audio system, a CD player, an MP3 player or the like.

The electronic device 140 may communicate 142 via a telecommunication network 101 with the system 110. Thus, the electronic device 140 may e.g. send information to the system 110. The telecommunication network 101 may be a wired or wireless network, such as a landline telecommunication network, public switched network, a Third Generation Partnership Project (3GPP) network, a Long Term Evolution (LTE) network, a Global System for Mobile Communications (GSM) network, a Universal Mobile Telecommunication System (UMTS) network, a Worldwide Interoperability for Microwave Access (WiMAX) network, a wireless network from among the 802.11-standard suit of networks or the like.

The structure 100 may also comprise a music provider 150, such as server hosting a music service like Spotify, Wiimp, LastFM, Pandora Radio, iTunes Radio or the like. The music provider 150 may communicate 151, e.g. via a wired or wireless connection, with the system 110.

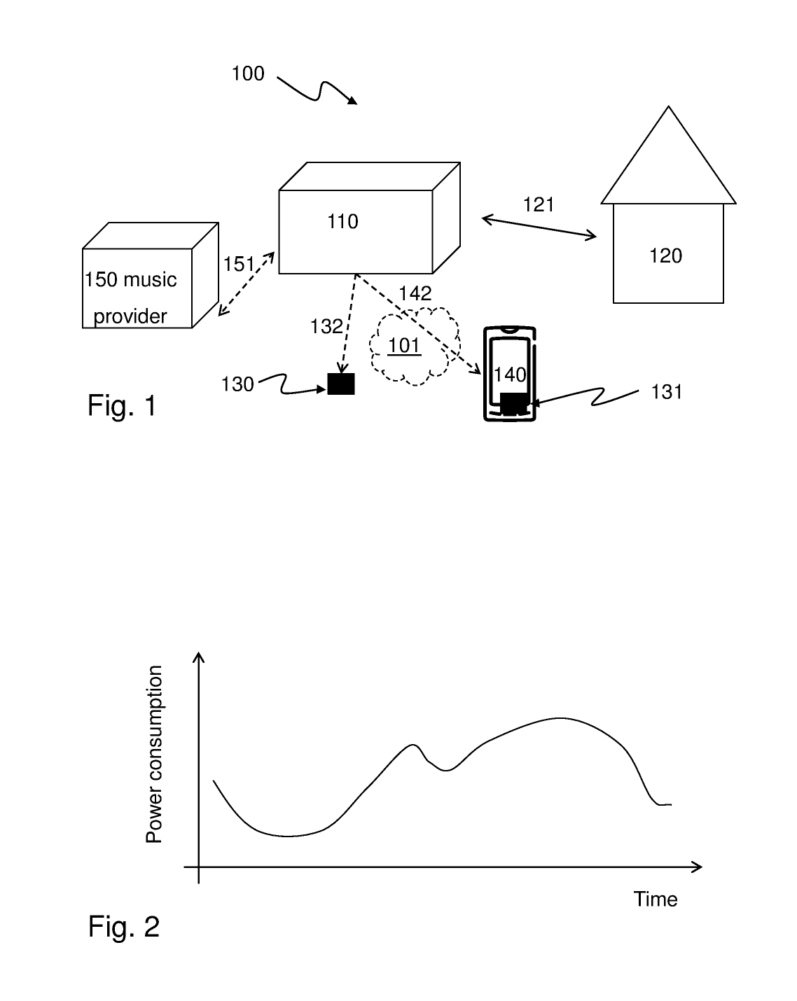

In order to better appreciate the description of the embodiments herein, it is here provided a brief explanation of how sound data may be determined based on power consumption. Thus, FIG. 2 shows an exemplifying a graph representing a sequence of measurements of power consumption as a function of time.

If the graph in FIG. 2 is treated as a sound wave plot, possibly after certain conversion or mapping, power consumption can be turned into an audible notification. This process is referred to as sonification herein.

It won't be very pleasant to listen to the audible notification with exactly the same graph as in FIG. 2 because it may a representation of noise. However, by applying sound wave matching, music with similar section as the graph can be found, and that music can be played on the phone, the home audio system, etc. Sound matching is a well-known in the art and will not be elaborated here for sake of simplicity. Theoretically, another exemplifying power consumption graph will result in another piece of music.

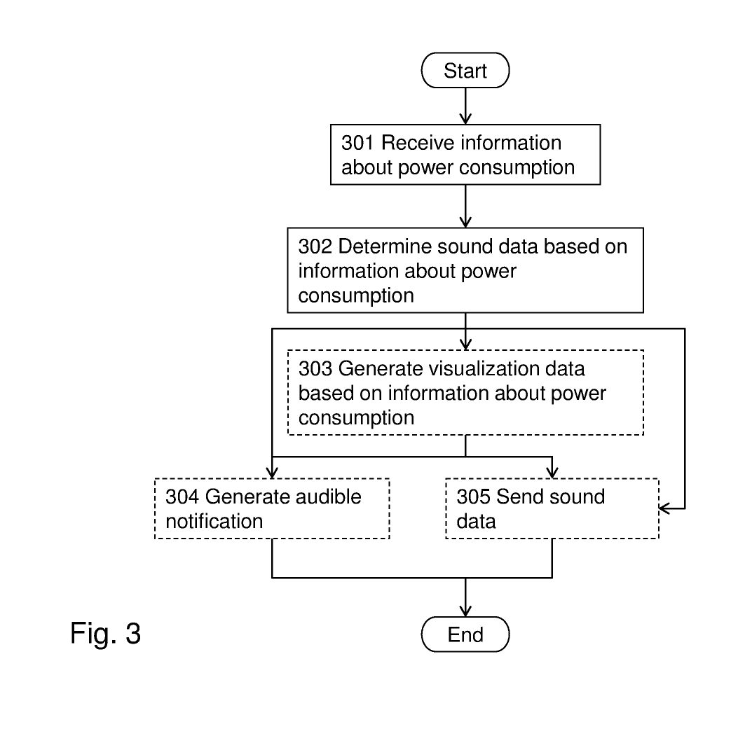

FIG. 3 illustrates an exemplifying method according to embodiments herein when performed in connection with the structure 100 of FIG. 1. The system 110 performs a method for providing sound data for generation of an audible notification relating to power consumption at the site 120.

As mentioned, the site 120 may comprise a set of electrical appliances of a house, an office, an industry or a building or part thereof. This means that the electrical appliances may be located in-doors or in proximity of the site, e.g. outside but still associated to the site. When an electrical appliance is located outside the site, the user's actions still affect the power consumption of the electrical appliance.

One or more of the following actions may be performed in any suitable order.

### Action 301

The system 110 receives information about power consumption at the site 120. As an example, the system 110 may receive one or more points to build a graph, such as the exemplifying graph in FIG. 2. Each point may be associated to a value indicating power consumption and a point in time. Possibly, the point may be associated to a certain power meter if more than one power meter may provide data about power consumption to the system 110.

The information may be received, denoted 121 in FIG. 1, from the site 120. The information may be sent by one or more power meters at the site 120, by a node collecting information about power consumption from power meters at the site 120 or the like. The site 120 may thus include said one or more power meters, the node collecting information or a similar entity.

### Action 302

The system 110 determines the sound data based on the information about power consumption and on preference of a user of the system 110. The audible notification may be audible to said user.

The preference of the user may be expressed in many different manners.

The preference of the user may relate to volume of the audible notification in relation to the power consumption. This means that the power consumption may be treated volume of the audible notification. Therefore, the audible notification, such as music, may get louder when power consumption increases and vice versa. More expressed, the volume of the audible notification may be set relatively a current volume, or at absolute values of the volume in relation to the power consumption.

In one example, an increase of the volume may correspond to an increase of the power consumption and a decrease of the volume may correspond to a decrease of the power consumption, in absolute values or relatively a current volume setting of the audible notification. Accordingly, higher volume means higher power consumption. In other examples, it may be the opposite, i.e. higher volume may correspond to lower power consumption.

In another example, the user may predefine a set of sound data, e.g. a couple of music clips, to play when power consumption reaches different thresholds, shown as following table:

| Power consumption | Sound clip |
|---|---|
| <100 w | 1.wav |
| >= 100 w <500 w | 2.wav |
| >= 500 w | 3.wav |

This means that a sound clip as selected by the user is played when power consumption currently is within a certain interval.

Each of the sound clips, as example of sound data, may be indicated by a respective indication. Hence, the preference of the user may include a set of indications associated to a respective level of the power consumption. Each indication may indicate a respective sound data, or sound clip, for generation of the audible notification.

Accordingly, the sound data may be represented by an indication associated with the sound data. In more detail, the system 110 may send a configuration command, which carries the indication, such as an integer or other value. It may then be that the system 110 and the electronic device 140 both are aware of that the integer represents certain sound data, e.g. by negotiation between the system 110 and the electronic device 140 or by (pre-)configuration of system 110 and the electronic device 140.

In further examples, the sound data may represent a piece of music. As a consequence, the audible notification may also comprise the piece of music.

The music may be computer-generated music, e.g. generated by an algorithm, using different frequency and/or amplitude in the generated sound waves, or sound data, to signify events such as peak power consumption.

The user of the system may customize the sound data by changing some of parameter, like a “Electronic-like” or a “More dissonant” option. As an example, this website http://computoser.com, retrieved on 6 Oct. 2014, runs this kind of algorithm as service generating music.

The music may be selected by the user. For example, the music may include a favourite song of the user.

As an additional example, the preference of the user may relate to pace of the audible notification in relation to the power consumption. The pace of the audible notification may be set relatively a current pace, or at absolute values of the pace in relation to the power consumption.

This means that the power consumption may e.g. be tied to the tempo, or pace, of the music. Additionally, if the power consumption peaks the system 110 may e.g. swap mood of the music from Major to Minor.

In a typical example, the pace of the sound data, i.e. the audible notification when generated, increases when power consumption increases. This is particularly applicable when the sound data represents the piece of music.

According to yet another example, the preference of the user may relate to number of instruments of the audible notification in relation to the power consumption. The number of instruments of the audible notification may be set relatively a current number of instruments, or to absolute numbers in relation to the power consumption. In more detail, a new instrument may for example be inserted in a mix of the music represented by the sound data. When combining this example one of the examples above, the sound data represent music selected by the user, such as a favourite song.

According to a still further example, a type of an instrument reflects the power consumption. The instrument is of course one of the instruments that are present in the sound data representing the audible notification. In more detail, this means that the preference of the user may relate to type of instrument of the audible notification in relation to the power consumption. The type of instrument of the audible notification may be set in relation to the power consumption. Types of instrument may be drum, violin, piano, cello, oboe, clarinet, chimes, etc. Hence, typically the drum may be used to represent high power consumption whereas for example the violin may be used to represent low power consumption.

Moreover, the preference of the user may relate to type of instrument of the audible notification in relation to power consumption of an appliance associated to the type of instrument. This means that the site may be equipped with a power meter for each appliance that one wishes to represent with a certain type of instrument. For example, a dishwasher may be associated to a first type of instrument, such as cello, and a coffee machine may be associated to a second type of instrument, such as a flute. In short, each appliance is associated to a respective instrument.

The information about power consumption may in some cases be analysed in order to distinguish power consumption of one or more individual appliances. An analysing technique is often referred to as a disaggregation technique, which is known in the art. The disaggregation technique is used to identify an active appliance/device in the site 120, such as a home, only by measuring a total power consumption and by learning individual power consumption patterns for each appliance of the site 120. Then the user may assign an instrument to a few of energy-hungry appliances/devices, e.g. a guitar to a refrigerator, and multiple instruments could be playing together. A human ear has the ability to distinguish different instruments by listening all of them to play at once because sounds have different timbre. Since different instruments playing totally different songs may result to a bad experience this embodiment could assign a different appliance to a different instrument of a musical score or a DJ mix that includes multiple instruments or tracks. Then, the volume of a certain instrument could be modulated by its power consumption. As a result the home owner could distinguish the level or severity in power consumption for multiple devices/appliances simultaneously.

Thus, it is not necessary that the site includes one power meter for each appliance of the site. Accordingly, the examples given in this paragraph may be applied even with only one power meter at the site.

Furthermore, the above mentioned example may be combined with the example in which the volume of the audible notification is indicative of the power consumption. Hence, a volume of the type of instrument associated to the appliance may be set relatively a current volume, or at absolute values of the volume in relation to the power consumption of the appliance. Expressed differently, volume of different instruments, reflect power consumption of particular appliance.

Moreover, the preference of the user may relate to a list of favourite songs, which list may be received, denoted 151 in FIG. 1, from the music provider 150. In an example, one song from the list is randomly picked by the system 110. That song may then be represented in the form of the sound data.

A few combinations of the examples are given above. Further combinations of the examples may be realized, each combination having its own particular advantages.

### Action 303

According to an embodiment, the system 110 may generate visualization data based on the information about power consumption and preference of a user of the system 110. The visualization data may represent a visualization relating to the power consumption.

Accordingly, the audible notification is combined with a user preferred visualization in order to provide a both audible and visual notification of the power consumption. In this manner, the user may at easy pay attention to the information about power consumption. Thus, a user-friendly and attractive, both in terms of audibility and visualization, interface for providing information about the power consumption at the site is provided.

Action 303 may be performed before or after one or more of actions 304 and 305 below.

### Action 304

As mentioned above, the system 110 may include means, such as a speaker, for generation of the audible notification. In these examples, the system 110 may generate the audible notification based on the sound data. In this manner, the sound data is rendered audible to a user of the system 110.

### Action 305

The system 110 may send the sound data to a further means (not shown) for generating the audible notification. The further means may be the speaker device 130, 131. The sending of the sound data to the further means may preferably be performed as an alternative to action 304 described above, i.e. when action 304 is not performed. However, action 305 may also be performed in combination with action 304, either before or after action 304.

In a first embodiment, the electronic device 140 is located outside the site 120. Furthermore, the electronic device 140 may comprise the speaker device 131. The sending is then performed by sending the sound data via the telecommunication network 101. Thus, remote notification of the power consumption is enabled. A home owner, as an example of the user, may connect the system 110 with an application on a connected device, e.g. a mobile phone, that plays music and while listening to the music the home owner may receive auditory feedback about the power consumption at the site 120, e.g. the home, periodically or in response to fault situations. The user could hence receive the audible notification even when not present at the site 120. See also communication 142 in FIG. 1.

In a second embodiment, the speaker device 130 may be connected to the system 110 by means of connection adapted for transferring of the sound data and data related to the sound data. See also communication 132 in FIG. 1.

In an office environment, as an exemplifying site, the first case may be preferred since users in the office may have different preferences. With the first case, the electronic device is provided with headphones which are carried by the users.

In an industry environment, as an exemplifying site, generation of audible notifications in the form of music may not be allowed or welcome. Therefore, the embodiments in which predefined sound waves, such as alarm clips, may be preferred. These predefined sound waves may be generated, or played, and altered to reflect current power consumption according to the embodiments herein.

In a further embodiment, the site 120 may be divided into sections, such as rooms, spaces, floors, stories or the like. The system 110 may have knowledge about which appliances are associated to which section. The system 110 may also keep track of power consumption of these appliances. In this embodiment, the system 110 may further keep track of, e.g. by means of that the electronic device 140 reports its position to the system 110, in which section the electronic device 140 currently is located. By combining a current section, in which the electronic device 140 is present at the moment, and the knowledge about which appliances are in that section and their associated power consumption, the system 110 may provide sound data, reflecting the power consumption of the appliances in the current section.

The system 110 is based on sonification of power consumption while taking the preference of the user into account. The system 110 produces sound data of different amplitude and frequency, which sound data represents audible sounds, to indicate changes in power consumption triggered from a user action. The generated sound data is adapted to the preference of the user.

In this manner, information about power consumption is utilized to retrieve, remix or generate sound data to make users aware of power consumption at the site in an audible way.

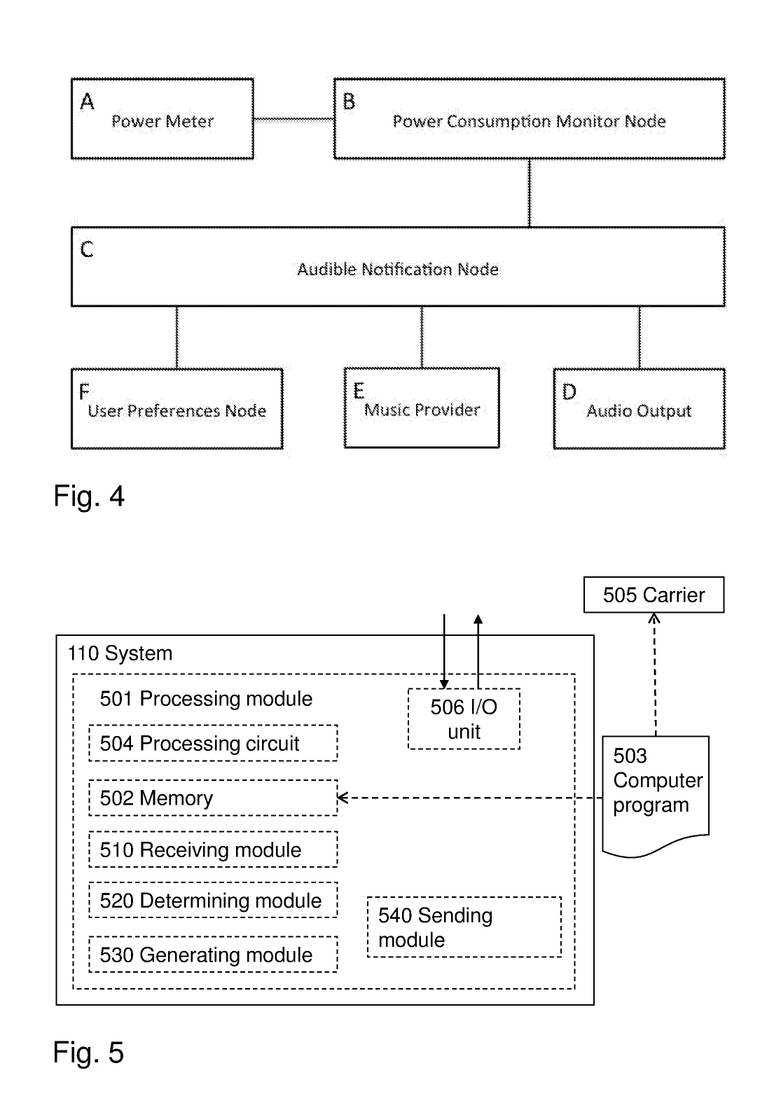

FIG. 4 illustrates an example of the system 110. This example is provided purely for illustrative purposes. As shown in FIG. 5 below, various realizations of the system 110 are provided herein.

In this example however, the system 110 comprises several logical modules: a power meter A, a power consumption monitor module B, an audible notification module C, an audio output D, a user preference module F and an optional module: a music provider E. Notably, the system 110 need not comprise the power meter A and the audio output D.

The different modules do in this example not represent physical devices. A single module may be distributed across multiple physical devices, as well as multiple modules being located in one physical device.

The power meter A is configured to provide information about the power consumption at the site, e.g. an electrical network that is monitored. The power meter A may be a pre-existing meter that the system 110 interfaces against, or one that is installed as part of the system 110. The power meter A may also be assumed that it is equipped with a processor to perform disaggregation of the total power consumption to individual device/appliance power consumption. An alternative may be to include power meters on each of the most energy consuming devices and those power meters would report to one central place locally in at the site, such as a home or office environment. Then, in a similar way as with only one power meter, the individual device/appliance power consumption may be collected in one place.

The power consumption monitor module B is configured to collect data from the power meter, the disaggregation module or the individual appliance power meters and compiles it in a way that is useful to the audible notification module C. The power consumption data may be used in many different ways as described above. The audible notification module C in turn uses the compiled data to determine what should be sent to the audio output D.

Some embodiments require a source of music, which in that case is provided by the music provider E. The music provider E may be a music service such as Spotify or some other source of music, e.g. music stored directly on a connected permanent storage media or accessed via a network connection.

The preference module F is configured to provide an interface where parameters to the system 110 may be configured. The preference module F may e.g. be used to set the volume of the audio output or select a list of songs or any other parameters required by the possible embodiments herein.

In an embodiment, the preference module F may be a physical device where the user can configure the system 110 using e.g. a touchscreen, voice input, or any other form of User Interface (UI).

In another embodiment, the preference module may be accessible via a network, e.g. a web server serving a web page or providing an Application Programming Interface (API). These two embodiments may also be combined into a device with a UI that also is accessible via the network.

In another embodiment, a separate system may be added that renders the power consumption in some other form, e.g. visualization. The separate system may be connected either to the power meter A or power consumption monitor module B. The preference module F may then also have the role of selecting which system should be used.

Schematically, FIG. 4 includes:
A. Power meter: a device which provides information about the total power use or individual device/appliance power use if it performs disaggregation
B. Power consumption monitor module: Compiles the information from the power meter or individual device/appliance power meters in a way that is more practical for the audible notification module
C. Audible notification module: Controls the playback of the audio using the information provided by the power consumption monitor module
D. Audio output: Used for audio playback, e.g. speakers.
E. Music provider: A service that provides a selection of music
F. User preferences module: Provides an interface for customization of the system.

With reference to FIG. 5, a schematic block diagram of embodiments of the system 110 of FIG. 1 is shown. The system 110 is thus configured to provide sound data for generation of an audible notification relating to power consumption at a site 120.

The system 110 may comprise a processing module 501, such as a means, one or more hardware modules and/or one or more software modules for performing the methods described herein.

The system 110 may further comprise a memory 502. The memory may comprise, such as contain or store, a computer program 503.

According to some embodiments herein, the processing module 501 comprises, e.g. ‘is embodied in the form of’ or ‘realized by’, a processing circuit 504 as an exemplifying hardware module. In these embodiments, the memory 502 may comprise the computer program 503, comprising computer readable code units executable by the processing circuit 504, whereby the system 110 is operative to perform the methods of FIG. 3.

In some other embodiments, the computer readable code units may cause the system 110 to perform the method according to FIG. 3 when the computer readable code units are executed by the system 110.

FIG. 5 further illustrates a carrier 505, comprising the computer program 503 as described directly above. The carrier 505 may be one of an electronic signal, an optical signal, a radio signal, and a computer readable medium.

In some embodiments, the processing module 501 comprises an Input/Output unit 506, which may be exemplified by a receiving module and/or a sending module as described below when applicable.

In further embodiments, the processing module 501 may comprise one or more of a receiving module 510, a determining module 520, a generating module 530 and a sending module 540 as exemplifying hardware modules. In other examples, one or more of the aforementioned exemplifying hardware modules may be implemented as one or more software modules.

Therefore, according to the various embodiments described above, the system 110 is operative to and/or the system 110, the processing module 501 and/or the receiving module 510 is configured to receive information about power consumption at the site 120.

The system 110 is further operative to and/or the system 110, the processing module 501 and/or the determining module 520 is further configured to determine the sound data based on the information about power consumption and on preference of a user of the system 110.

Moreover, the system 110 may be operative to and/or the system 110, the processing module 501 and/or the generating module 530 may be configured to generate the audible notification based on the sound data, whereby the sound data may be rendered audible to a user of the system 110.

Furthermore, the system 110 may be operative to and/or the system 110, the processing module 501 and/or the sending module 540 may be configured to send the sound data to a speaker device 131, whereby the speaker device 120 may be capable of generating the audible notification based on the sound data.

An electronic device 140, located outside the site 120, may comprise the speaker device 131, wherein the system 110 may be configured to send the sound data via a telecommunication network 101.

The speaker device 131 may be connected to the system 110 by means of connection adapted for transferring of the sound data and data related to the sound data.

The system 110 may further be operative to and/or the system 110, the processing module 501 and/or the generating module 530 may further be configured to generate visualization data based on the information about power consumption and preference of a user of the system 110, wherein the visualization data may represent a visualization relating to the power consumption.

According to the embodiments described herein, the follow embodiments of the system 110 are provided.

The preference of the user may relate to volume of the audible notification in relation to the power consumption, wherein the volume of the audible notification may be set relatively a current volume, or at absolute values of the volume in relation to the power consumption.

An increase of the volume may correspond to an increase of the power consumption and a decrease of the volume may correspond to a decrease of the power consumption, in absolute values or relatively a current volume setting of the audible notification.

The preference of the user may include a set of indications associated to a respective level of the power consumption, wherein each indication may indicate a respective sound data for generation of the audible notification.

The audible notification may comprise a piece of music.

The preference of the user may relate to pace of the audible notification in relation to the power consumption, wherein the pace of the audible notification may be set relatively a current pace, or at absolute values of the pace in relation to the power consumption.

The preference of the user may relate to number of instruments of the audible notification in relation to the power consumption, wherein the number of instruments of the audible notification may be set relatively a current number of instruments, or to absolute numbers in relation to the power consumption.

The preference of the user may relate to type of instrument of the audible notification in relation to the power consumption, wherein the type of instrument of the audible notification may be set in relation to the power consumption.

The preference of the user may relate to type of instrument of the audible notification in relation to power consumption of an appliance associated to the type of instrument.

A volume of the type of instrument associated to the appliance may be set relatively a current volume, or at absolute values of the volume in relation to the power consumption of the appliance.

The site 120 may comprise a set of electrical appliances of a house, an office, an industry or a building or part thereof.

The audible notification may be audible to said user.

As used herein, the term “processing module” may include one or more hardware modules, one or more software modules or a combination thereof. Any such module, be it a hardware, software or a combined hardware-software module, may be a determining means, estimating means, capturing means, associating means, comparing means, identification means, selecting means, receiving means, sending means or the like as disclosed herein. As an example, the expression “means” may be a module corresponding to the modules listed above in conjunction with the Figures.

As used herein, the term “processing circuit” may refer to a processing unit, a processor, an Application Specific integrated Circuit (ASIC), a Field-Programmable Gate Array (FPGA) or the like. The processing circuit or the like may comprise one or more processor kernels.

As used herein, the expression “configured to” may mean that a processing circuit is configured to, or adapted to, by means of software configuration and/or hardware configuration, perform one or more of the actions described herein.

As used herein, the term “memory” may refer to a hard disk, a magnetic storage medium, a portable computer diskette or disc, flash memory, random access memory (RAM) or the like. Furthermore, the term “memory” may refer to an internal register memory of a processor or the like.

As used herein, the term “computer readable medium” may be a Universal Serial Bus (USB) memory, a DVD-disc, a Blu-ray disc, a software module that is received as a stream of data, a Flash memory, a hard drive, a memory card, such as a MemoryStick, a Multimedia Card (MMC), etc.

As used herein, the term “computer readable code units” may be text of a computer program, parts of or an entire binary file representing a computer program in a compiled format or anything there between.

As used herein, the term “radio resource” may refer to a certain coding of a signal and/or a time frame and/or a frequency range in which the signal is transmitted. In some examples, a resource may refer to one or more Physical Resource Blocks (PRB) which is used when transmitting the signal. In more detail, a PRB may be in the form of Orthogonal Frequency Division Multiplexing (OFDM) PHY resource blocks (PRB). The term “physical resource block” is known from 3GPP terminology relating to e.g. Long Term Evolution Systems.

As used herein, the terms “number” and/or “value” may be any kind of digit, such as binary, real, imaginary or rational number or the like. Moreover, “number” and/or “value” may be one or more characters, such as a letter or a string of letters. “Number” and/or “value” may also be represented by a bit string.

As used herein, the expression “in some embodiments” has been used to indicate that the features of the embodiment described may be combined with any other embodiment disclosed herein.

Even though embodiments of the various aspects have been described, many different alterations, modifications and the like thereof will become apparent for those skilled in the art. The described embodiments are therefore not intended to limit the scope of the present disclosure.

1. A method, performed by a system for providing sound data for generation of an audible notification relating to power consumption at a site, wherein the method comprises:
receiving information about power consumption at the site; and
determining the sound data based on the information about power consumption and on preference of a user of the system.

2. The method of claim 1, wherein the method further comprises:
generating the audible notification based on the sound data, whereby the sound data is rendered audible to a user of the system.

3. The method of claim 1, wherein the method comprises:
sending the sound data to a speaker device, whereby the speaker device is capable of generating the audible notification based on the sound data.

4. The method of claim 3, wherein an electronic device, located outside the site, comprises the speaker device, wherein the sending includes sending the sound data via a telecommunication network.

5. The method of claim 3, wherein the speaker device is connected to the system by means of connection adapted for transferring of the sound data and data related to the sound data.

6. The method of claim 1, wherein the method further comprises:
generating visualization data based on the information about power consumption and preference of a user of the system, wherein the visualization data represents a visualization relating to the power consumption.

7. The method of claim 1, wherein the preference of the user relates to volume of the audible notification in relation to the power consumption, wherein the volume of the audible notification is set relatively a current volume, or at absolute values of the volume in relation to the power consumption.

8. The method of claim 7, wherein an increase of the volume corresponds to an increase of the power consumption and a decrease of the volume corresponds to a decrease of the power consumption, in absolute values or relatively a current volume setting of the audible notification.

9. The method of claim 1, wherein the preference of the user includes a set of indications associated to a respective level of the power consumption, wherein each indication indicates a respective sound data for generation of the audible notification.

10. The method of claim 1, wherein the audible notification comprises a piece of music.

11. The method of claim 10, wherein the preference of the user relates to pace of the audible notification in relation to the power consumption, wherein the pace of the audible notification is set relatively a current pace, or at absolute values of the pace in relation to the power consumption.

12. The method of claim 10, wherein the preference of the user relates to number of instruments of the audible notification in relation to the power consumption, wherein the number of instruments of the audible notification is set relatively a current number of instruments, or to absolute numbers in relation to the power consumption.

13. The method of claim 10, wherein the preference of the user relates to type of instrument of the audible notification in relation to the power consumption, wherein the type of instrument of the audible notification is set in relation to the power consumption.

14. The method of claim 10, wherein the preference of the user relates to type of instrument of the audible notification in relation to power consumption of an appliance associated to the type of instrument.

15. The method of claim 14, wherein a volume of the type of instrument associated to the appliance is set relatively a current volume, or at absolute values of the volume in relation to the power consumption of the appliance.

16. The method of claim 1, wherein the site comprises a set of electrical appliances of a house, an office, an industry or a building or part thereof.

17. The method of claim 1, wherein the audible notification is audible to said user.

18. A system configured to provide sound data for generation of an audible notification relating to power consumption at a site, wherein the system is configured to:
receive information about power consumption at the site; and
determine the sound data based on the information about power consumption and on preference of a user of the system.

19. The system of claim 18, wherein the system is configured to generate the audible notification based on the sound data, whereby the sound data is rendered audible to a user of the system.

20. The system of claim 18, wherein the system is configured to send the sound data to a speaker device, whereby the speaker device is capable of generating the audible notification based on the sound data.

21. The system of claim 20, wherein an electronic device, located outside the site, comprises the speaker device, wherein the system is configured to send the sound data via a telecommunication network.

22. The system of claim 20, wherein the speaker device is connected to the system by means of connection adapted for transferring of the sound data and data related to the sound data.

23. The system of claim 18, wherein the system is configured to generate visualization data based on the information about power consumption and preference of a user of the system, wherein the visualization data represents a visualization relating to the power consumption.

24. The system of claim 18, wherein the preference of the user relates to volume of the audible notification in relation to the power consumption, wherein the volume of the audible notification is set relatively a current volume, or at absolute values of the volume in relation to the power consumption.

25. The system of claim 24, wherein an increase of the volume corresponds to an increase of the power consumption and a decrease of the volume corresponds to a decrease of the power consumption, in absolute values or relatively a current volume setting of the audible notification.

26. The system of claim 18, wherein the preference of the user includes a set of indications associated to a respective level of the power consumption, wherein each indication indicates a respective sound data for generation of the audible notification.

27. The system of claim 18, wherein the audible notification comprises a piece of music.

28. The system of claim 27, wherein the preference of the user relates to pace of the audible notification in relation to the power consumption, wherein the pace of the audible notification is set relatively a current pace, or at absolute values of the pace in relation to the power consumption.

29. The system of claim 27, wherein the preference of the user relates to number of instruments of the audible notification in relation to the power consumption, wherein the number of instruments of the audible notification is set relatively a current number of instruments, or to absolute numbers in relation to the power consumption.

30. The system of claim 27, wherein the preference of the user relates to type of instrument of the audible notification in relation to the power consumption, wherein the type of instrument of the audible notification is set in relation to the power consumption.

31. The system of claim 27, wherein the preference of the user relates to type of instrument of the audible notification in relation to power consumption of an appliance associated to the type of instrument.

32. The system of claim 31, wherein a volume of the type of instrument associated to the appliance is set relatively a current volume, or at absolute values of the volume in relation to the power consumption of the appliance.

33. The system of claim 18, wherein the site comprises a set of electrical appliances of a house, an office, an industry or a building or part thereof.

34. The system of claim 18, wherein the audible notification is audible to said user.

35. A computer program product comprising a non-transitory computer readable medium storing a computer program, comprising computer readable code units which when executed on a system causes the system to perform the method of claim 1.

36. (canceled)
